(19) United States
(12) Patent Application Publication
(10) Pub. No.: US 2021/0033916 A1
(43) Pub. Date: Feb. 4, 2021

(54) DISPLAY APPARATUS

(71) Applicant: CANON KABUSHIKI KAISHA, Tokyo (JP)

(72) Inventors: Tasuku Uchimi, Chigasaki-shi (JP); Tetsuya Ishida, Kawasaki-shi (JP)

(21) Appl. No.: 16/939,493

(22) Filed: Jul. 27, 2020

(30) Foreign Application Priority Data
Jul. 29, 2019 (JP) 2019-139047
Dec. 20, 2019 (JP) 2019-230311

(51) Int. Cl. G02F 1/1333; H05K 7/20

(52) U.S. Cl. CPC G02F 1/133385; G06F 3/147; H05K 7/20963; H05K 7/20972

(57) ABSTRACT

A display apparatus according to the present invention includes: a display module configured to display an image; and an air blowing member provided on a rear-surface side of the display module to blow air toward a rear surface of the display module, wherein a first exhaust port for exhausting the air blown from the air blowing member to an outside is formed in a side surface of the display apparatus, the first exhaust port being larger in size than a region obtained by projecting, on the side surface, a space formed between the display module and the air blowing member.

### BACKGROUND OF THE INVENTION

### Field of the Invention

The present invention relates to a display apparatus.

### Description of the Related Art

Display apparatuses include a so-called 4K high-definition display apparatus having a horizontal definition (the number of pixels) of about 4000 pixels and a so-called 8K ultra-high-definition display apparatus. In a liquid-crystal display panel, as a definition increases, a transmissivity decreases. Accordingly, in a liquid-crystal display module (display module including a liquid-crystal panel and a backlight module), as the definition of the liquid-crystal panel increases, a brightness of the backlight module is required to be increased.

There is also a so-called high-dynamic-range (HDR) display apparatus capable of displaying an image in a wide dynamic range (brightness range having a high maximum brightness). To allow a liquid-crystal display module to display an image with a high brightness, it is required to increase a brightness of a backlight module thereof. Of the HDR display apparatus, a brightness of not less than 1000 cd/m² may be required. In addition, power consumed by a power source that drives the display module may be not less than several hundreds of watts or may also be not less than 1000 W.

To increase the brightness of the backlight module, a large number of light-emitting diodes (LEDs) are used as a light source of the backlight module and, to drive the large number of LEDs, it is intended to increase an output and a size of the power source and use a plurality of the power sources.

The increase of the brightness of the backlight module (such as the increase of the number of the LEDs) increases an amount of heat generated from the backlight module. When heat dissipation from (cooling of) the backlight module is insufficient, the heat from the backlight module may cause malfunction of various electronic components. For example, increased temperatures of the LEDs having temperature characteristics may cause a reduction in brightness of each of the LEDs, color deviation, a reduction in light emission efficiency of the LED, and a reduction in lifetime of the LED.

Even in a display module having a spontaneous-emission-type display panel such as an organic EL panel or a plasma panel, a light source (display element such as an organic EL element or a plasma element) of the display panel is required to have a higher brightness, and consequently the same problem as encountered by the liquid-crystal display module is encountered.

To prevent such a problem, an air blowing member (e.g., a fan) for cooling the display module may be provided in the display apparatus. For example, in a display apparatus disclosed in Japanese Patent Application Publication No. 2019-3014, a plurality of fans facing a rear surface of a backlight module are provided so as to individually blow air to a plurality of respective areas of the rear surface of the backlight module.

When a display apparatus is used in an environment in which capturing, editing, and the like of an image is performed, it is required to minimize noise from the display apparatus. However, in the display apparatus including the air blowing member, noise due to the air blowing member occurs to prevent the noise minimization. Particularly when a display module is required to have a higher brightness, the noise due to the air blowing member is conspicuously observed. Specifically, since the higher brightness of the display module increases an amount of heat generation, it is required to increase an amount of air blown by the air blowing member (to cause a fan to rotate at a higher speed). As the amount of the air blown by the air blowing member is increased (as the number of the rotations of the fan is increased), the noise due to the air blowing member increases.

Japanese Patent Application Publication No. 2012-73636 discloses a projector which achieves noise minimization through control of an internal space thereof. Specifically, in the projector described in Japanese Patent Application Publication No. 2012-73636, a heat source (such as a light source) is disposed in a first case (upper case), a fan is disposed in a second case (lower case), and the first case and the second case are combined with each other to be movable relative to each other. As a result of moving one of the first case and the second case upon projection, a space is formed between the fan and the heat source to reduce a flow rate of air exhausted from the fan and reduce noise.

However, the projector disclosed in Japanese Patent Application Publication No. 2012-73636 needs a complicated configuration (mechanism) for moving at least one of the first case and the second case.

### SUMMARY OF THE INVENTION

The present invention provides a technique which can reduce, using a simple configuration, noise due to an air blowing member for cooling a display module.

A first display apparatus according to the present invention includes:

a display module configured to display an image; and

an air blowing member provided on a rear-surface side of the display module to blow air toward a rear surface of the display module, wherein

a first exhaust port for exhausting the air blown from the air blowing member to an outside is formed in a side surface of the display apparatus, the first exhaust port being larger in size than a region obtained by projecting, on the side surface, a space formed between the display module and the air blowing member.

A second display apparatus according to the present invention includes:

a display module configured to display an image; and

a main body unit provided on a rear-surface side of the display module, wherein

an intermediate extending unit to be disposed between the display module and the main body unit is attachable to the display apparatus;

when the intermediate extending unit is not attached to the display apparatus, an engagement portion to be located on the rear-surface side of the display module and an engagement portion to be located in the main body unit are disposed so as to be connected to each other; and,

when the intermediate extending unit is attached to the display apparatus, an engagement portion to be located on a main-body-unit side of the intermediate extending unit and the engagement portion located in the main body unit are disposed so as to be connected to each other.

A third display apparatus according to the present invention includes:

a display module configured to display an image; and

a main body unit provided on a rear-surface side of the display module, wherein

an intermediate extending unit to be disposed between the display module and the main body unit is attachable to the display apparatus;

when the intermediate extending unit is not attached to the display apparatus, an engagement portion to be located on the rear-surface side of the display module and an engagement portion to be located in the main body unit are disposed so as to be connected to each other; and,

when the intermediate extending unit is attached to the display apparatus, an engagement portion to be located on a main-body-unit side of the intermediate extending unit, the engagement portion to be located in the main body unit, and a portion of an exterior of the display module are disposed so as to be connected to each other.

Further features of the present invention will become apparent from the following description of exemplary embodiments with reference to the attached drawings.

### BRIEF DESCRIPTION OF THE DRAWINGS

FIG. 1 is a perspective view illustrating an outer appearance of a display apparatus according to a first embodiment;

FIG. 2 is a cross-sectional view of the display apparatus according to the first embodiment;

FIG. 3 is an exploded perspective view illustrating a configuration of a display module according to the first embodiment;

FIG. 4 is a cross-sectional view illustrating air flow paths in the display apparatus according to the first embodiment;

FIG. 5 is a cross-sectional view illustrating the air flow paths in the display apparatus according to the first embodiment;

FIG. 6 is a rear view of a backlight module according to the first embodiment;

FIG. 7 is a rear view illustrating air flow paths according to the first embodiment;

FIG. 8 is a perspective view illustrating an outer appearance of a display apparatus according to a second embodiment;

FIG. 9 is a cross-sectional view of the display apparatus according to the second embodiment;

FIG. 10 is a cross-sectional view illustrating air flow paths in the display apparatus according to the second embodiment;

FIG. 11 is a cross-sectional view illustrating the air flow paths in the display apparatus according to the second embodiment;

FIG. 12 is a cross-sectional view of a display apparatus according to a comparative example;

FIG. 13 is a perspective view illustrating an outer appearance of a display apparatus according to a third embodiment;

FIGS. 14A and 14B are assembly diagrams of the display apparatuses according to the first and third embodiments;

FIG. 15 is a cross-sectional view illustrating air flow paths in the display apparatus according to the third embodiment;

FIG. 16 is a perspective view illustrating an outer appearance of a display apparatus according to a fourth embodiment;

FIGS. 17A and 17B are assembly diagrams of the display apparatus according to the fourth embodiment; and

FIG. 18 is a block diagram of a display apparatus according to a fifth embodiment.

### DESCRIPTION OF THE EMBODIMENTS

### First Embodiment

The following will describe a first embodiment of the present invention. While an example in which the present invention is applied to a liquid-crystal display apparatus is described, a display apparatus to which the present invention is applicable is not limited to the liquid-crystal display apparatus. For example, the present invention may also be applied to another transmission-type display apparatus such as a micro-electro-mechanical-system (MEMS) shutter display apparatus using a MEMS shutter instead of a liquid-crystal element. Alternatively, the present invention may also be applied to a spontaneous-emission-type display apparatus such as an organic EL display apparatus or a plasma display apparatus.

In the first embodiment, a surface of the display apparatus having a display surface on which an image is to be displayed is defined as a “front surface” and a surface of the display apparatus opposite to the front surface is defined as a “rear surface”, while other surfaces (surfaces connecting the front surface and the rear surface) are defined as “side surfaces”. Viewing the display apparatus while facing the front surface is defined as “front surface viewing”, while viewing the display apparatus while facing any of the side surfaces is defined as “side surface viewing”. In a “front surface viewing” state, the side surface positioned on an upper side is defined as an “upper surface” or “top surface”, the side surface located on a right side is defined as a “right surface”, the side surface located on a left side is defined as a “left surface”, and the side surface located on a lower side is defined as a “lower surface” or “bottom surface”.

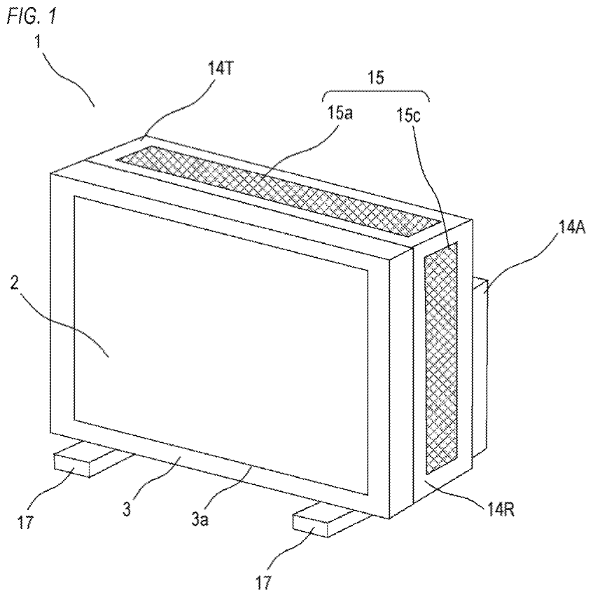

FIG. 1 is a perspective view illustrating an outer appearance of a display apparatus 1 according to the first embodiment. An exterior of the display apparatus 1 includes a bezel 3, cases 14T, 14A, and 14R, and the like, and an opening 3a is formed in the bezel 3. From the opening 3a, a liquid-crystal panel 2 (display surface of the liquid-crystal panel 2) is exposed so as to allow an image displayed on the liquid-crystal panel 2 to be visually recognized. The case 14T is disposed to form the upper surface of the display apparatus 1, the case 14A is disposed to form the rear surface thereof, and the case 14R is disposed to form the right surface thereof. Around the display apparatus 1, exhaust ports 15 (ventilation holes) are formed to exhaust internally absorbed air. In the upper-surface case 14T of the display apparatus 1, an exhaust port 15a is formed while, in the right-surface case 14R, an exhaust port 15c is formed. A case 14L (not shown) similar to the case 14R is disposed on the left surface of the display apparatus 1 and, in the case 14L, an exhaust port 15b (not shown) similar to the exhaust port 15c is formed. The exhaust ports 15a to 15c are formed of, e.g., a plurality of holes opened in a metal plate or the like. The exhaust ports 15a to 15c may be formed of a plurality of holes opened in the cases 14T, 14L, and 14R or may also be formed of a plurality of holes opened in a punching material bonded to the cases 14T, 14L, and 14R. On the bottom surface of the display apparatus 1, a stand 17 for allowing the display apparatus 1 to stand is provided. When the display apparatus 1 is placed on a desk or the like, the stand 17 allows a space to be provided between the bottom surface of the display apparatus 1 and a placement surface (surface of the desk or the like) on which the display apparatus 1 is placed.

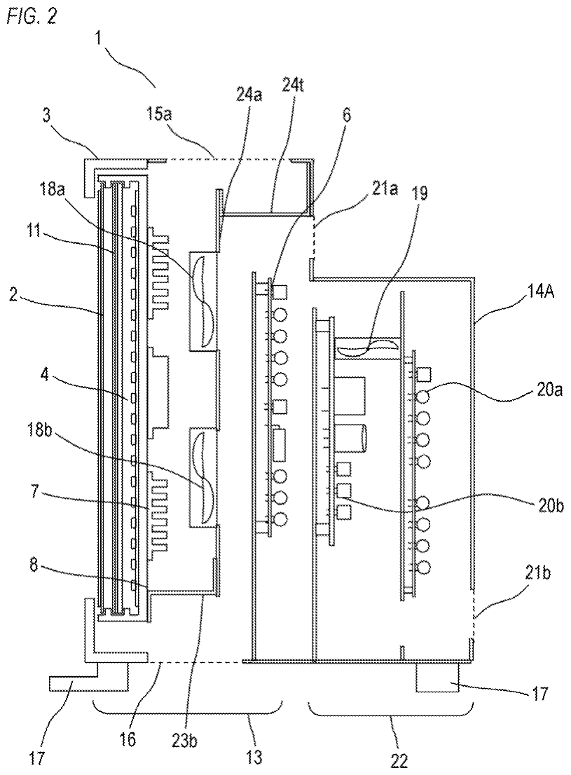

FIG. 2 is a view obtained by viewing the display apparatus 1 from the right side (right side surface) thereof, which is a cross-sectional view of a center portion of the display apparatus 1. The display apparatus 1 includes a display module 13 including the liquid-crystal panel 2, a main body unit 22 on a rear-surface side, and the like. On the rear-surface side of the display module 13, a plurality of air blowing members, specifically fans 18a to 18f (of which the fans 18c to 18f are not shown) are disposed. The fans 18a to 18f are disposed so as to blow air (exhaust air) toward the rear surface of the display module 13. Note that the air blowing members need not necessarily be the fans as long as the air blowing members can blow air. The number of the air blowing members is also not particularly limited.

The fans 18a to 18f are attached to a support member 24a. The support member 24a is supported by a connection member 23b, a support member 24t, and the like. In the bottom surface of the display apparatus 1, an inlet port 16 is formed to take in air (outside air) for cooling an inside of the display apparatus 1. The inlet port 16 is also formed of, e.g., a plurality of holes opened in a metal plate or the like. The inlet port 16 may be formed of a plurality of holes opened in a case or may also be formed of a plurality of holes opened in a punching material bonded to the case. A drive substrate 6 disposed in a substantially middle portion of the display apparatus 1 is an electrical substrate (electrical board) for driving the liquid-crystal panel 2 of the display module 13 or a light source thereof.

In the main body unit 22, a plurality of electrical substrates are embedded. An electrical substrate 20a is a signal processing substrate that transmits an image signal to the display module 13. An electrical substrate 20b is a power source substrate that supplies electrical power to the electrical substrate 20a and to the display module 13.

To allow the inside of the display apparatus 1 (inside of the main body unit 22) to be cooled, a rear-surface inlet port 21b is formed in the case 14A. Through driving of a rear-surface fan 19, the air (outside air) for cooling the display apparatus 1 (main body unit 22) is taken in through the rear-surface inlet port 21b to be able to cool the electrical substrates 20a and 20b and the like. In addition, in an upper part (portion on an upper-surface side) of the case 14A also, a rear-surface inlet port 21a is provided. When the fans 18a to 18f are driven, the air (outside air) for cooling the display apparatus 1 (display module 13) is taken in through the rear-surface inlet port 21a and transmitted toward the display module 13.

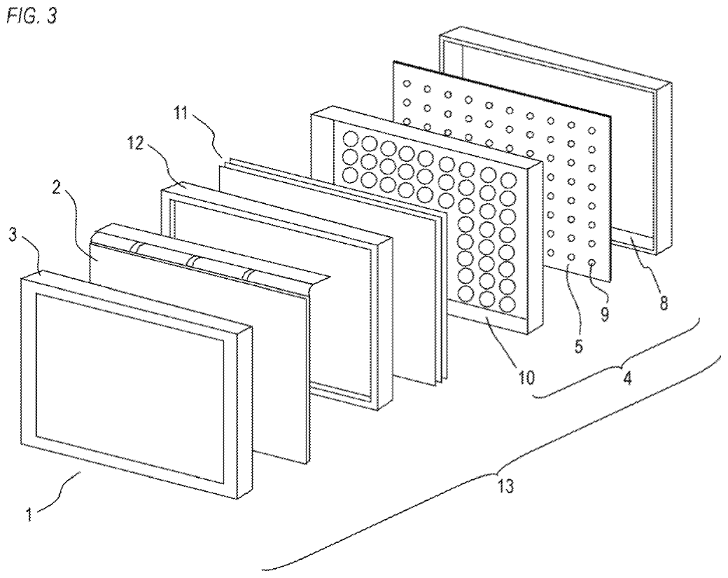

FIG. 3 is an exploded perspective view illustrating a configuration of the display module 13. In the display apparatus 1, the bezel 3 is disposed on a front-surface side of the liquid-crystal panel 2, while a backlight module 4 is disposed on the rear-surface side of the liquid-crystal panel 2. The backlight module 4 is a light-emitting module that irradiates the rear surface of the liquid-crystal panel 2 with light. The liquid-crystal panel 2, which is light-transmissive, transmits the light emitted from the backlight module 4 to display an image. The backlight module 4 includes a light source substrate 5, the drive substrate 6 (see FIG. 2), heat sinks 7 (see FIG. 2), a case 8, and the like.

On the light source substrate 5, a plurality of light-emitting diodes (LEDs) 9 are provided. The light source provided on the light source substrate 5 is not limited to the LEDs, and may also be a cold cathode fluorescent lamp (CCFL) or the like. On the front-surface side of the light source substrate 5, a reflection sheet 10 is disposed to efficiently reflect light emitted from the light source substrate 5 and diffused toward the liquid-crystal panel 2. On the front-surface side of the reflection sheet 10, optical sheets 11 are disposed to diffuse/condense the light from the reflection sheet and thus reduce unevenness of the light to be applied to the liquid-crystal panel 2 and improve a brightness of the light. On the front-surface side of the optical sheets 11, a panel holder 12 is disposed to press the optical sheets 11 and the like and support the liquid-crystal panel 2 from the rear-surface side.

The case 8 covers the light source substrate 5 from the rear-surface side such that, to the case 8, the light source substrate 5 is fixed. The heat sinks 7 are fixed to the rear surface of the case 8, while being in thermally intimate contact with the case 8 with a heat transmission member (not shown) or the like being interposed between the heat sinks 7 and the case 8. In the first embodiment, the plurality of heat sinks 7 are fixed to the rear surface of the case 8. Heat generated from the light source substrate 5 is released into a space on the rear-surface side of the heat sinks 7 through the heat sinks 7. Note that the case 8 and the heat sinks 7 may also be integrally configured.

The various members varying from the bezel 3 to the backlight module 4 illustrated in FIG. 3, the drive substrate 6 (see FIG. 2), the heat sinks 7 (see FIG. 2), and the like configure the display module 13. In such a configuration, the rear surface of the backlight module 4 serves as the rear surface of the display module 13. Note that, instead of the heat sinks 7, another heat dissipation member may also be provided. Alternatively, a heat dissipation member such as the heat sinks 7 need not necessarily be provided.

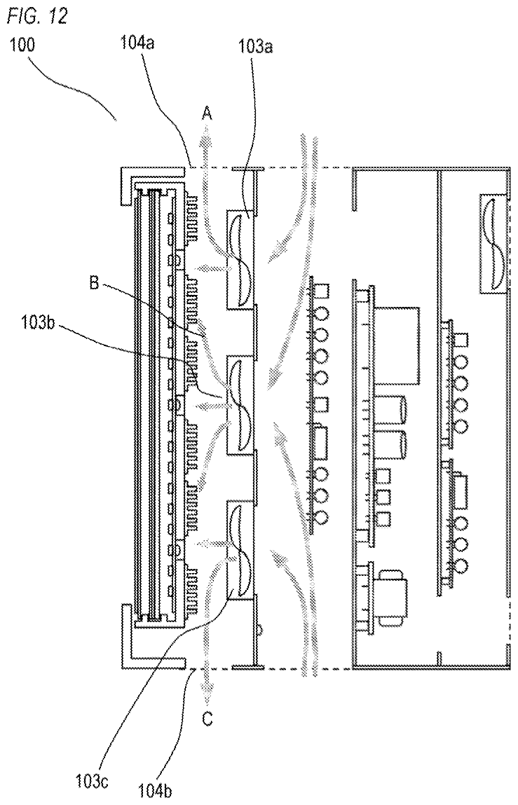

An example of a problem to be solved by the first embodiment is described herein. FIG. 12 is a view obtained by viewing a display apparatus 100 according to a comparative example from the right side (right-surface side), which is a cross-sectional view of the center portion of the display apparatus. Fans 103a, 103b, and 103c are disposed on the rear-surface side of the backlight module. Air exhausted from the fans 103a, 103b, and 103c passes through a space on the rear-surface side of the backlight module to be exhausted to the outside through exhaust ports 104a and 104b formed in the upper surface and the bottom surface of the display apparatus 100, as indicated by arrows A to C. The space on the rear-surface side of the backlight module is a space formed between the backlight module and each of the fans 103a, 103b, and 103c. A region occupied by the exhaust port 104a is equal to a region obtained by projecting the space on the rear-surface side of the backlight module on the upper surface of the display apparatus 100. A region occupied by the exhaust port 104b is equal to a region obtained by projecting the space on the rear-surface side of the backlight module on the lower surface of the display apparatus 100. Consequently, a flow rate of the exhausted air is not considerably reduced, and loud wind noise is generated through the exhaust ports 104a and 104b (noise increase due to the fans 103a, 103b, and 103c).

Also, as indicated by the arrow C, the air is exhausted downwardly from the display apparatus 100. As a result, the air may collide with a placement surface (surface of a desk or the like) on which the display apparatus 100 is placed and flow to a user side. When the air exhausted from the display apparatus 100 flows to the user side, the noise (such as the wind noise described above) due to the fans 103a, 103b, and 103c is likely to be heard by the user.

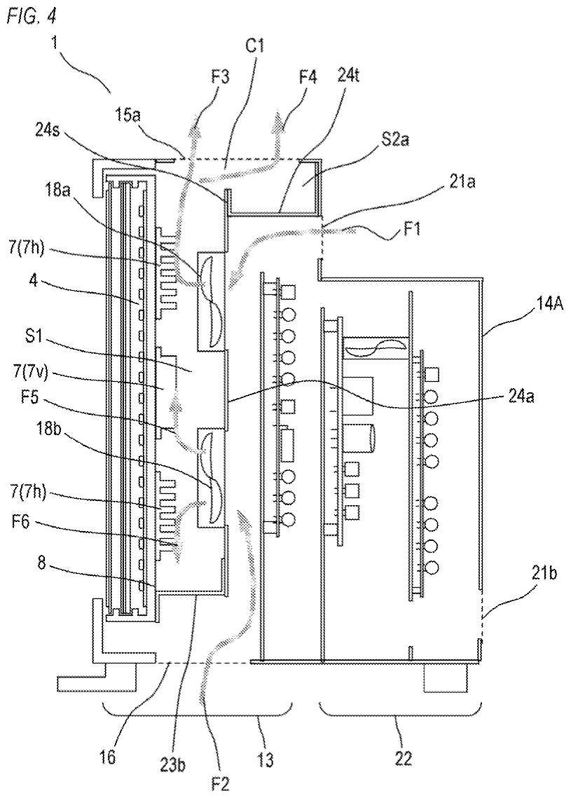

Returning back to the description of the first embodiment, FIG. 4 is a cross-sectional view similar to FIG. 2 and illustrates air flow paths in the display apparatus 1. As indicated by an arrow F2, the fans 18a and 18b disposed on the rear-surface side of the backlight module 4 take in air (outside air) through the inlet port 16. As indicated by an arrow F1, the fans 18a and 18b further take in air (outside air) through the rear-surface inlet port 21a. Then, the fans 18a and 18b exhaust the air taken in thereby to the rear-surface side of the display module 13 (backlight module 4). The air exhausted from the fans 18a and 18b flows as indicated by arrows F3 to F6 to be exhausted to the outside through the exhaust port 15a in the upper surface. Heat generated in the backlight module 4 is transmitted to the heat sinks 7 and then from the heat sinks 7 to the air (heat transmission). Then, the air heated by the heat from the backlight module 4 is exhausted to the outside through the exhaust port 15a (heat dissipation).

A description will be given of the air flows indicated by the arrows F3 and F4 while paying attention on the upper part of the display apparatus 1. In the upper part of the display apparatus 1, the support member 24t is attached to the support member 24a to which the fans 18a and 18b are attached. The support member 24t has a generally U-shaped cross section, and a space S2a is formed within the support member 24t. On the rear-surface side of the display module 13 (backlight module 4), a space S1 is formed. The space S1 is a space formed between the backlight module 4 and each of the fans 18a and 18b. Specifically, the space S1 is a space interposed between each of the backlight case 8 and the heat sinks 7 and the support member 24a. Thus, in an inner portion of the display apparatus 1 in which the exhaust port 15a is formed, a space having a width (width of the space S1+the space S2a) in a front-rear direction of the display apparatus 1 larger than a distance (width of the space S1) between the display module 13 and each of the fans 18a and 18b is formed.

A region occupied by the exhaust port 15a is larger than a region obtained by projecting the space S1 on the upper surface of the display apparatus 1. This allows a reduction in the flow rate of the air exhausted through the exhaust port 15a and a reduction in wind noise generated through the exhaust port 15a (a reduction in noise due to the fans 18a and 18b).

Specifically, the air exhausted from the fans 18a and 18b passes through the space S1 to be exhausted to the outside through the exhaust port 15a, as indicated by the arrow F3. The support member 24a and the support member 24t are engaged with each other via a connection portion 24s. However, since the connection portion 24s is spaced apart from the exhaust port 15a, the space S1 and the space S2a are connected to each other via a communicating portion C1. Consequently, the air exhausted from the fans 18a and 18b passes through the communicating portion C1 to flow even into the space S2a and be exhausted through the exhaust port 15a, as indicated by the arrow F4. Thus, it is possible to allow the air exhausted from the fans 18a and 18b to be exhausted through the wider exhaust port 15a, reduce the flow rate of the exhausted air, and reduce noise.

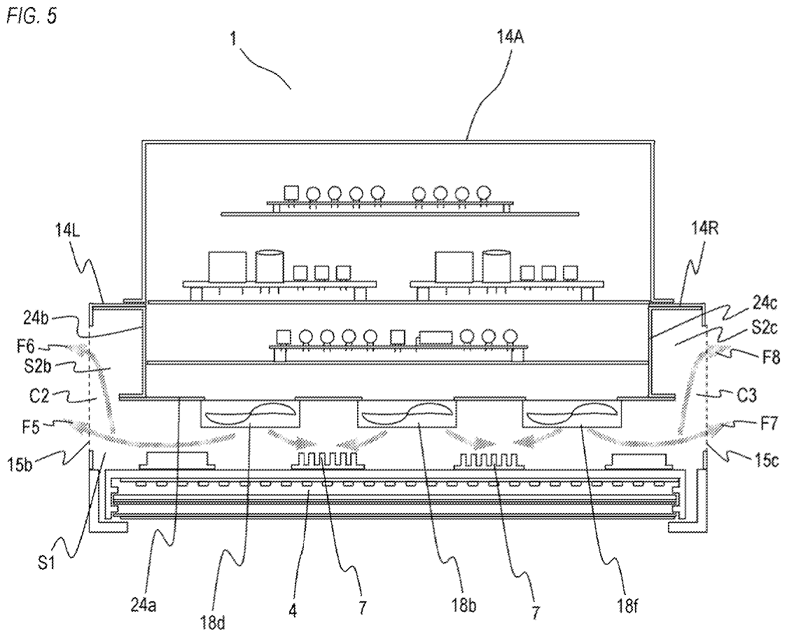

FIG. 5 is a view obtained by viewing the display apparatus 1 from above (from the upper-surface side thereof), which is a cross-sectional view of the center portion of the display apparatus 1. Using FIG. 5, another air flow path in the display apparatus 1 (flow path in a horizontal direction (lateral direction) of the display apparatus 1) will be described. The fans 18b, 18d, and 18f exhaust the air taken in thereby to the rear-surface side of the backlight module 4. The air exhausted from the fans 18b, 18d, and 18f flows as indicated by arrows F5 to F8 to be exhausted to the outside through the exhaust port 15b in the left surface and the exhaust port 15c in the right surface.

In the first embodiment, similarly to the exhaust port 15a, a region occupied by the exhaust port 15b is larger than a region obtained by projecting the space S1 on the left surface of the display apparatus 1, while a region occupied by the exhaust port 15c is larger than the region obtained by projecting the space S1 on the left surface of the display apparatus 1. As a result, it is possible to achieve a reduction in wind noise generated through the exhaust ports 15b and 15c (reduction in noise due to the fans 18b, 18d, and 18f).

Specifically, to both ends of the support member 24a to which the fans 18b, 18d, and 18f are attached, the support members 24b and 24c are attached, in the same manner as in the upper part. Each of the support members 24b and 24c also has a generally U-shaped cross section, similarly to the support member 24t, and, in the support members 24b and 24c, respective spaces S2b and S2c are formed. The space S1 on the rear-surface side of the backlight module 4 is connected to the spaces S2b and S2c via the communicating portions C2 and C3. The air exhausted from the fans 18b, 18d, and 18f passes through the space S1 to be exhausted to the outside through the exhaust ports 15b and 15c, as indicated by the arrows F5 and F7. The air exhausted from the fans 18b, 18d, and 18f further passes through the communicating portions C2 and C3 to flow even into the spaces S2b and S2c and be exhausted through the exhaust ports 15b and 15c, as indicated by the arrows F6 and F8. This allows the air exhausted from the fans 18b, 18d, and 18f to be exhausted through the wider exhaust ports 15b and 15c, allows a reduction in the flow rate of the exhausted air, and allows a reduction in noise.

Each of the exhaust ports 15a to 15c is disposed to extend between the space S1 and the corresponding one of the spaces S2a to S2c (the exhaust ports 15a, 15b, and 15c respectively correspond to the spaces S2a, S2b, and S2c). In other words, each of the exhaust ports 15a to 15c is formed so as to include a region obtained by projecting the space S1 on a corresponding surface (the exhaust ports 15a, 15b, and 15c respectively correspond to the upper surface, the left surface, and the right surface).

Note that the surfaces in which the exhaust ports are formed need not necessarily be the upper surface, the right surface, and the left surface. The number of the surfaces in which the exhaust ports are formed is not particularly limited. It may also be possible that the exhaust port is formed only in one of the side surfaces of the display apparatus 1.

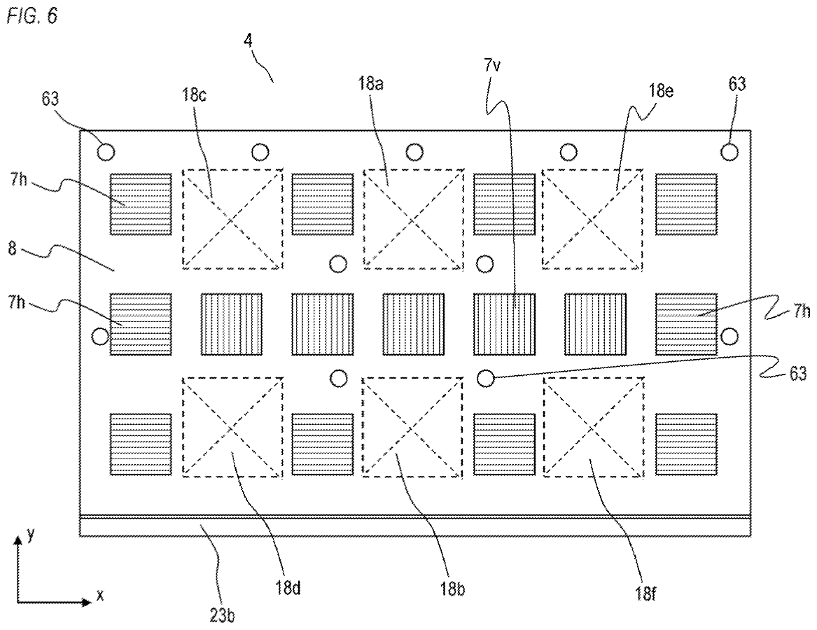

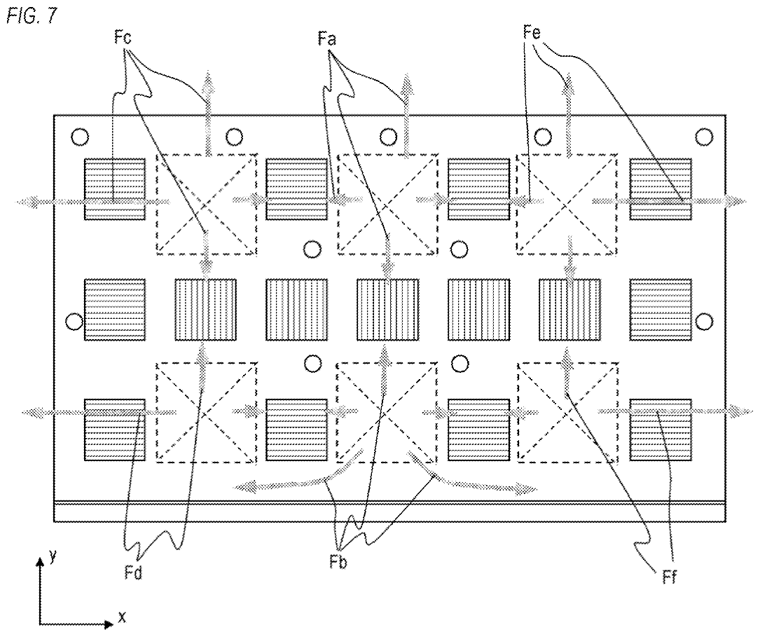

FIG. 6 is a rear view of the backlight module 4. FIG. 7 is a rear view illustrating air flow paths of air flowing along the rear surface of the backlight module 4.

The fans 18a to 18f are disposed in flat shapes on the rear-surface side of the backlight module 4. Heat sinks 7h and 7v are disposed on the rear surface of the backlight module 4 (backlight case 8). The display module 13 and the main body unit 22 each illustrated in FIG. 4 are connected to each other via a plurality of connection members 63 and the connection member 23b. The plurality of connection members 63 are provided on the rear surface of the display module 13 (backlight case 8) to erect and be engaged with the support member 24a (see FIG. 4). Accordingly, the plurality of connection members 63 fix the fans 18a to 18f to the display module 13. The connection member 23b is disposed in a lower part (portion closer to the upper surface) of the display module 13 to be connected to the support member 24a. In FIG. 6, the support members 63 are metallic cylindrical bosses, but may also be members each having another column shape such as a rectangular column shape. The connection member 23b is a member formed of a plate or the like. As illustrated in FIG. 4, the connection member 23b is a wall-shaped member disposed in the lower part of the display module 13.

In FIG. 7, the flows of the air from the fans 18a to 18f are indicated by arrows. The arrow Fa indicates the flow of the air from the fan 18a. The arrow Fb indicates the flow of the air from the fan 18b. The arrow Fc indicates the flow of the air from the fan 18c. The arrow Fd indicates the flow of the air from the fan 18d. The arrow Fe indicates the flow of the air from the fan 18e. The arrow Ff indicates the flow of the air from the fan 18f As indicated by the arrows Fa to Ff in FIG. 7, the air from each of the fans 18a to 18f collides with the rear surface of the backlight module 4, and then radially flows.

In the first embodiment, directions of fins of the heat sinks 7 are adjusted such that the heat sinks 7 do not interrupt the flows of the air from the fans 108a to 108f, i.e., such that the heat sinks 7 do not serve as a flow path resistance to the air from the fans 108a to 108f Specifically, the fins of the heat sinks 7 are oriented so as to extend along directions in which the air (air current) from the fans 108a to 108f flows. The heat sink 7h is the heat sink 7 disposed such that the fins thereof extend along an x-direction (lateral direction) in the drawing. The heat sink 7v is the heat sink 7 disposed such that the fins thereof extend along a y-direction (vertical direction) in the drawing. By disposing the heat sinks 7h and 7v as illustrated in FIG. 7, it is possible to allow the air exhausted from the fans 18a to 18f to efficiently flow to the exhaust ports 15a to 15c, and implement efficient air exhaust (heat dissipation). In addition, by using the columnar member as the support member 63, it is possible to reduce the likelihood that the support member 63 serves as a flow path resistance to the air from the fans 108a to 108f, and implement efficient air exhaust (heat dissipation). In addition, since each of the heat sink 7 and the support member 63 is less likely to serve as a flow path resistance, it is possible to reduce wind noise in these portions.

Also, in the first embodiment, in the lower surface of the display apparatus 1, exhaust ports for exhausting the air from the fans 108a to 108f to the outside are not formed. When attention is focused on the flows indicated by the arrow Fb, the air downwardly flowing from the display module 13 is interrupted by the connection member 23b (wall) so as not to be exhausted from the lower surface of the display apparatus 1. A portion of the air flow as indicated by the arrow Fb corresponds to the air flow indicated by the arrow F6 in FIG. 4. As described above, in the comparative example illustrated in FIG. 12, the exhaust port 104b is formed in the lower surface of the display apparatus 100. Accordingly, air is exhausted from the display apparatus 100 to the user side, and consequently the noise from the display apparatus 100 is more likely to be heard by the user. In the first embodiment, no exhaust port is formed in the lower surface of the display apparatus 1, and therefore it is possible to inhibit the air from being exhausted from the display apparatus 1 to the user side and reduce the likelihood that the noise from the display apparatus 1 is heard by the user.

As described heretofore, according to the first embodiment, it is possible to reduce noise due to the air blowing member for cooling the display module by using a simple configuration which exhausts the air for cooling the inside of the display apparatus to the outside through the relatively large exhaust ports. In addition, even when it is desired to improve the efficiency of heat dissipation from the display module for a higher brightness of the display module, it is possible to simultaneously improve the efficiency of heat dissipation from the display module and minimize noise from the display apparatus.

### Second Embodiment

The following will describe a second embodiment of the present invention. Note that the following will give a detailed description of a component different from those used in the first embodiment and omit a description of the same components as those used in the first embodiment as much as possible.

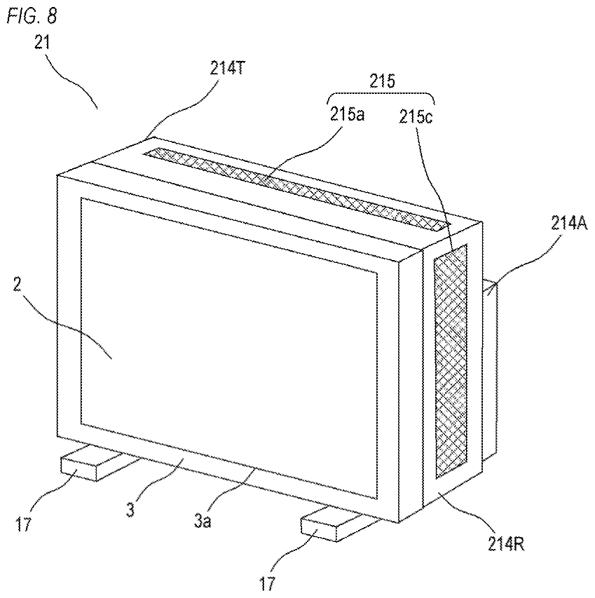

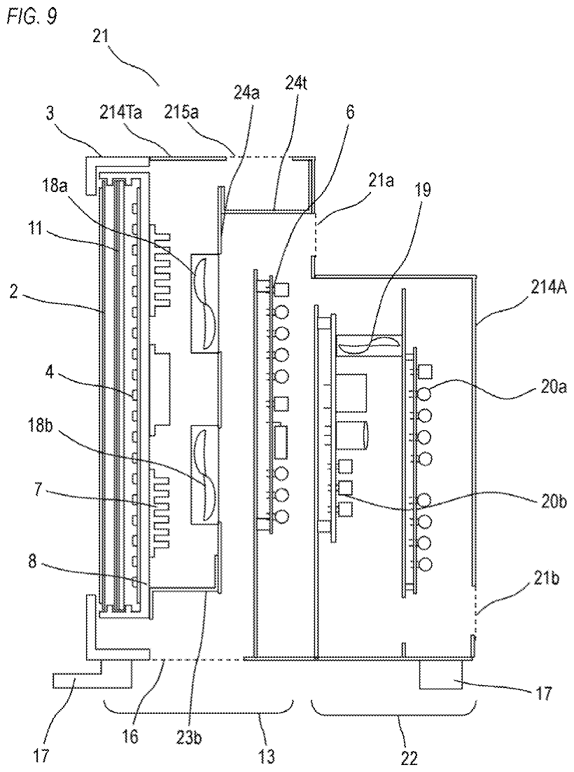

FIG. 8 is a perspective view illustrating an outer appearance of a display apparatus 21 according to the second embodiment. FIG. 9 is a view obtained by viewing the display apparatus 21 from a right side (right-surface side), which is a cross-sectional view of a center portion of the display apparatus 21. In FIGS. 8 and 9, the same members and portions as those used in the first embodiment are given the same reference numerals.

As illustrated in FIG. 8, an exterior of the display apparatus 21 includes the bezel 3, cases 214T, 214A, and 214R, and the like. The case 214T is disposed on the upper surface of the display apparatus 21. The case 214A is disposed on the rear surface of the display apparatus 21. The case 214R is disposed on the right surface of the display apparatus 21. Around the display apparatus 21, exhaust ports 215 (ventilation holes) are formed to exhaust internally absorbed air. In the upper-surface case 214T of the display apparatus 21, an exhaust port 215a is formed while, in the right-surface case 214R of the display apparatus 21, an exhaust port 215c is formed. A case 214L (not shown) similar to the case 214R is disposed on the left surface of the display apparatus 21 and, in the case 214L, an exhaust port 215b (not shown) similar to the exhaust port 215c is formed. As illustrated in FIG. 9, the main body unit 22 is the same as that used in the first embodiment. In other words, the display apparatus 21 has substantially the same configuration as that of the display apparatus 1 in the first embodiment (see FIG. 1).

The second embodiment is different from the first embodiment in a width and a position of the exhaust port 215a in a depth direction (front-rear direction). In the first embodiment, as illustrated in FIG. 1, the width and the position of the exhaust port 15a in the depth direction are substantially the same as those of the exhaust port 15b in the depth direction. In the second embodiment, as illustrated in FIG. 8, the width of the exhaust port 215a in the depth direction is smaller than the width of the exhaust port 215b in the depth direction, while the position of the exhaust port 215a in the depth direction is behind (on the rear-surface side of) the position of the exhaust port 215b in the depth direction.

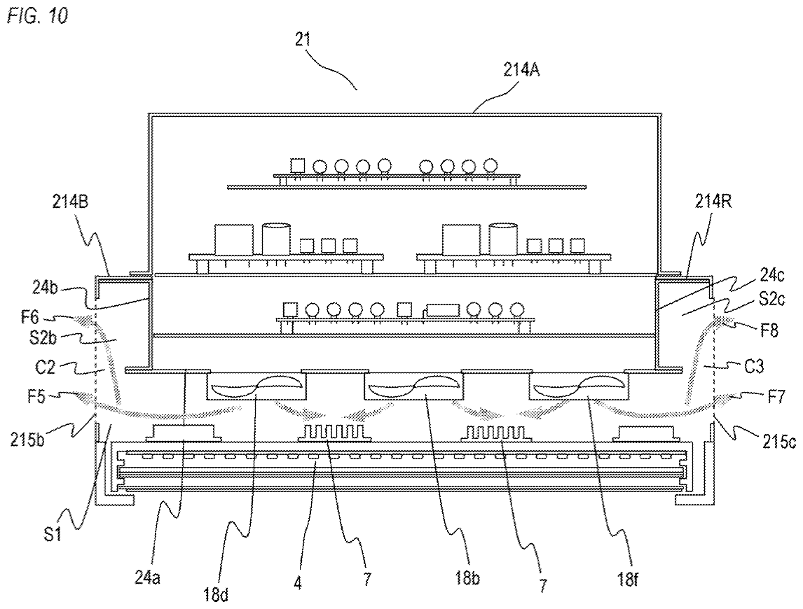

FIG. 10 is a view obtained by viewing the display apparatus 21 from above (from the upper-surface side), which is a cross-sectional view of the center portion of the display apparatus 21. Using FIG. 10, another air flow path in the display apparatus 21 (flow path in a horizontal direction (lateral direction) of the display apparatus 21) will be described.

In the same manner as in the first embodiment, the spaces S2b and S2c are present in the respective vicinities of the left surface and the right surface of the display apparatus 21 and connected to the space S1 on the rear-surface side of the backlight module 4. As indicated by the arrows F5 and F7, the air exhausted from the fans 18b, 18d, and 18f passes through the space S1 to be exhausted to the outside through the exhaust ports 215b and 215c. As indicated by the arrows F6 and F8, the air exhausted from the fans 18b, 18d, and 18f further passes through the communicating portions C2 and C3 to flow even into the spaces S2b and S2c and be exhausted through the exhaust ports 215b and 215c. In other words, using the same air flows as those used in the first embodiment, heat dissipation with reduced noise is performed.

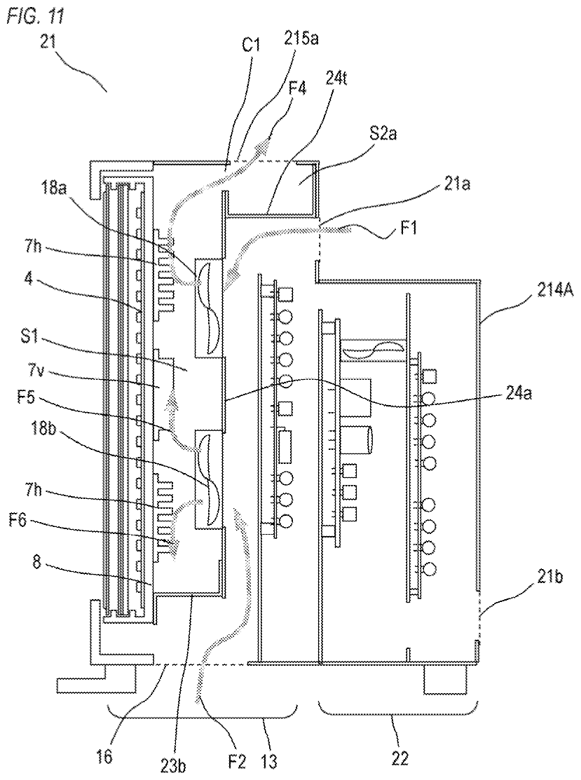

FIG. 11 is the same cross-sectional view as that of FIG. 9, which is a view illustrating air flow paths in the display apparatus 21 (flow paths in a perpendicular direction (vertical direction) in the display apparatus 21).

The exhaust port 215a is formed so as not to include the region obtained by projecting the space S1 on the upper surface. Specifically, the exhaust portion 215a is not formed in the upper part of the space S1 on the rear-surface side of the backlight module 4, but is formed only in the upper part of the space S2a within the supporting member 24t. Accordingly, as indicated by the arrow F4, the air exhausted from the fans 18a and 18b passes through the space S1, the communicating portion C1, and the space S2a to be exhausted to the outside through the exhaust port 215a. The exhaust port 215a described above can inhibit a foreign material that has entered the display apparatus 21 through the exhaust port 215a from reaching positions at which the inner fans and the other electrically charged members, such as electrical substrates, are provided and can inhibit a failure resulting from contact between any of the electrically charged members and the foreign material or the like.

As described above, according to the second embodiment, in the same manner as in the first embodiment, it is possible to reduce noise due to the air blowing member for cooling the display module by using a simple configuration which exhausts the air for cooling the inside of the display apparatus to the outside through the relatively large exhaust ports. In addition, by inventively modifying the regions occupied by some of the exhaust ports or the like, it is possible to inhibit the foreign material from entering the display apparatus.

Note that, as long as the exhaust ports are formed so as not to include the region obtained by projecting the space on the rear-surface side of the display module on the side surface, positions and shapes of the exhaust ports that inhibit the entrance of the foreign material into the display apparatus are not particularly limited. The surface in which the exhaust ports that inhibit the entrance of the foreign material into the display apparatus are formed are not limited to the upper surface, and may also be, e.g., the left surface or the right surface. The exhaust ports that inhibit the entrance of the foreign material into the display apparatus may also be formed in a plurality of surfaces. The surface in which the exhaust ports that inhibit noise are formed and the number of the surfaces in which the exhaust ports that inhibit noise are formed are also not particularly limited.

Note that the first and second embodiments (including the modification described above) are only exemplary. Configurations obtained by appropriately modifying or changing the configurations in the first and second embodiments within the gist of the present invention are also included in the present embodiment. A configuration obtained by appropriately combining the configurations in the first and second embodiments is also included in the present invention.

### Third Embodiment

In a third embodiment, a description will be given of a structure which allows for a higher brightness than achieved in the first and second embodiments. The structure according to the third embodiment can be obtained by (easily) extending each of structures described in the first and second embodiments. To allow for the higher brightness, dedicated design which permits efficient heat dissipation has been performed conventionally to produce a model entirely different from a prior art model. In the third embodiment, an extension unit (unit which extends the apparatus in the depth direction) attachable to (detachable from) the display apparatus described in the first or second embodiment, an existing display apparatus, or the like is used to provide a display apparatus capable of efficient heat dissipation so as to allow for a higher brightness.

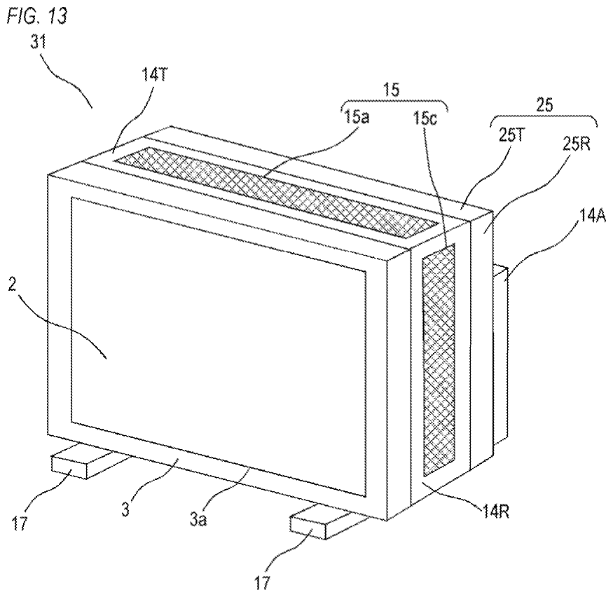

FIG. 13 is a perspective view illustrating an outer appearance of a display apparatus 31 according to the third embodiment. In the same manner as in FIG. 1 illustrating the first embodiment, an exterior of the display apparatus 31 includes the bezel 3, the cases 14T, 14A, and 14R, and the like. The case 14T is disposed to form the upper surface of the display apparatus 31. The case 14A is disposed on the rear surface of the display apparatus 31. The case 14R is disposed on the right surface of the display apparatus 31. A case (not shown) similar to the case 14R is disposed on the left surface of the display apparatus 31. In the case 14T, the exhaust port 15a is formed while, in the case 14R, the exhaust port 15c is formed. Air within the display apparatus 31 is exhausted from the exhaust ports 15a and 15c and the like. As a component different from those illustrated in FIG. 1, an intermediate extending unit 25 is provided between the case 14A disposed on the rear surface and each of the upper-surface case 14T and the right-surface case 14R in FIG. 13. An exterior of the intermediate extending unit 25 includes an upper-surface case 25T, a right-surface case 25R, and a left-surface case (not shown).

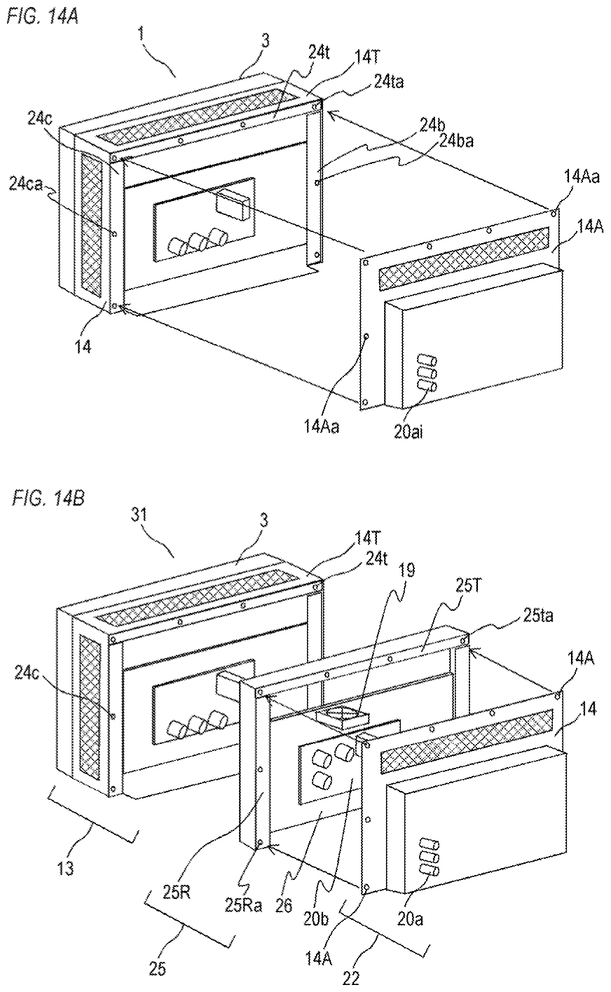

FIG. 14A is an assembly diagram of the display apparatus 1 according to the first embodiment. FIG. 14B is an assembly diagram of the display apparatus 31 according to the third embodiment.

On the rear surface of the display module 13 including the bezel 3 and the like, the support member 24t is disposed, and a plurality of engagement portions 24ta to which screws or the like are to be fastened are provided in the support member 24t. Likewise, on the rear surface of the display module 13, the support members 24b and 24c are disposed, and a plurality of engagement portions 24ba are provided in the support member 24b, while a plurality of engagement portions 24ca are provided in the support member 24c. Around the case 14A included in the main body unit 22 and disposed on the rear-surface side of the display module 13, engagement holes (engagement portions) 14Aa through which screws or the like (not shown) are to extend are disposed. On the rear surface of the case 14A, an image input unit 20ai for receiving an image signal input thereto from the outside, such as an interface, is provided. By inserting screws or the like through the engagement holes 14Aa and fastening the screws or the like to the engagement portions 24ta, the engagement holes 14Aa and the engagement portions 24ta are connected to each other to allow the main body unit 22 to be connected to the display module 13. Thus, the display apparatus 1 in FIG. 14A is completed.

The display apparatus 31 in FIG. 14B includes the intermediate extending unit 25 between the display module 13 and the main body unit 22. In the case 25T of the intermediate extending unit 25, engagement portions 25Ta to which screws or the like are to be fastened are provided. In the case 25R, engagement portions 25Ra are provided. Each of the engagement portions 25Ta and 25Ra is disposed on a main-body-unit side. In FIG. 14A, the engagement portions 24ta of the support member 24t are fastened to the engagement holes 14Aa of the case 14A, while the engagement portions 25ta (intermediate extending unit 25) are fastened herein to the engagement holes 14Aa using screws or the like to connect the intermediate extending unit 25 to the main body unit 22. The intermediate extending unit 25 is fastened to the display module 13 by using engagement portions (not shown) disposed at positions different from those of the engagement portions 24ta.

The intermediate extending unit 25 includes the electrical substrate 20b that supplies electrical power (electrical energy) to the backlight module 4, a chassis 26 supporting the electrical substrate 20b, and the rear-surface fan 19 for cooling the electrical substrate 20b. The electrical substrate 20b is already embedded in the main body unit 22 but, by adding the electrical substrate 20b embedded in the intermediate extending unit 25 thereto, it is possible to supply higher electrical power using the backlight module 4. In addition, it is possible to turn ON the backlight module 4 with a higher brightness.

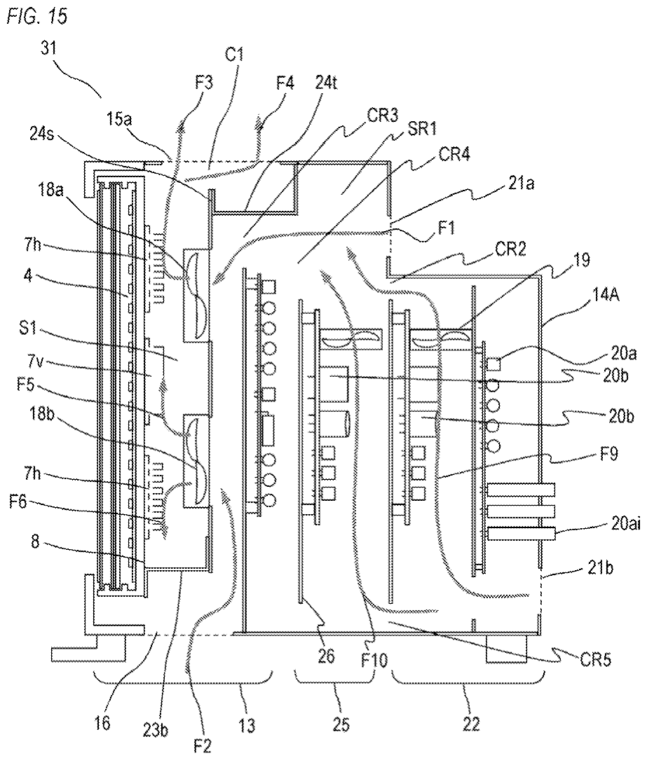

FIG. 15 is a cross-sectional view illustrating air flows in the display apparatus 31 according to the third embodiment. In FIG. 15, the same power source substrate 20b as the electrical substrate 20b disposed in the main body unit 22 is embedded also in the intermediate extending unit 25 on a display module 13 side. A description will be given herein of the air flow paths. Air that has entered the display apparatus 31 through the inlet port 21b (opening) provided in the lower part of the rear-surface-side case 14a passes through the main body unit 22 and the electrical substrate 20b of the intermediate extending unit 25 following arrows F9 and F10, and passes through the main body unit 22 and the rear-surface fan 19 of the intermediate extending unit 25. Then, the air joins the air (see the arrow F1) from the outside to flow into the backlight module 4. In the case of the first embodiment in which the intermediate extending unit 25 is not provided, the air passes only through the relatively narrow communicating portions CR2 and CR5 to flow into the display module 13. When the backlight module 4 is turned ON with a brightness which does not require the intermediate extending unit 25, even when communicating portions through which the air passes are only the communicating portions CR2 and CR5, satisfactory heat dissipation from (cooling of) the backlight module 4 is performed. However, when a higher brightness is required and when only the communicating portions CR2 and CR5 are provided, a flow path resistance increases and satisfactory heat dissipation may not be performed. By adding the intermediate extending unit 25, the space SR1 is formed, and relatively wide communicating portions CR4 and CR3 reduce the flow path resistance, and consequently the air is more likely to flow into the display module 13. Accordingly, the addition of the intermediate extending unit 25 prevents heat dissipation efficiency (cooling efficiency) from being impaired even when the brightness is increased, and it is possible to effect satisfactory heat dissipation from the backlight module 4. Note that, when the intermediate extending unit 25 is added, the communicating portion CR3 functions as a first communicating portion connecting a space within the intermediate extending unit and the space within the display module, while the communicating portions CR2 and CR5 function as a second communicating portion connecting the space within the intermediate extending unit and a space within the main body unit.

As described above, by additionally providing the intermediate extending unit between the display module and the main body unit by using the engagement portions (fastening portions) for connecting the main body unit to the display module, it is possible to (easily) extend a structure of the display apparatus and allow for a higher brightness.

Note that, in the third embodiment, the description has been given of the example in which the intermediate extending unit includes the electrical substrate (power source substrate) which supplies electrical power (electrical energy) to the display module. However, the electrical substrate included in the intermediate extending unit is not particularly limited. For example, the intermediate extending unit may also include an electrical substrate (control substrate) that controls the display module. Specifically, the intermediate extending unit may also include an additional control substrate for more accurately controlling the backlight module.

### Fourth Embodiment

A fourth embodiment is an embodiment obtained by modifying a component configuration of the intermediate extending unit described in the third embodiment.

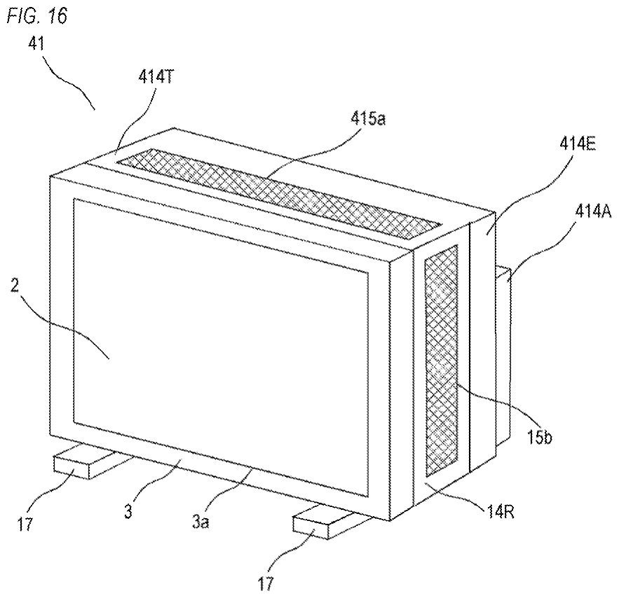

FIG. 16 is a perspective view illustrating an outer appearance of a display apparatus 41 according to the fourth embodiment. In the same manner as in the third embodiment, an exterior of the display apparatus 41 includes the bezel 3 and the case 14R, while an upper-surface case 414T is extended to the rear surface of the image display apparatus 41. On the rear-surface side of the side-surface case 14R, a case 414E is disposed. The case 414E is a portion of an intermediate extending unit 425 described later. On a rearmost surface of the display apparatus 41, a case 414A is disposed.

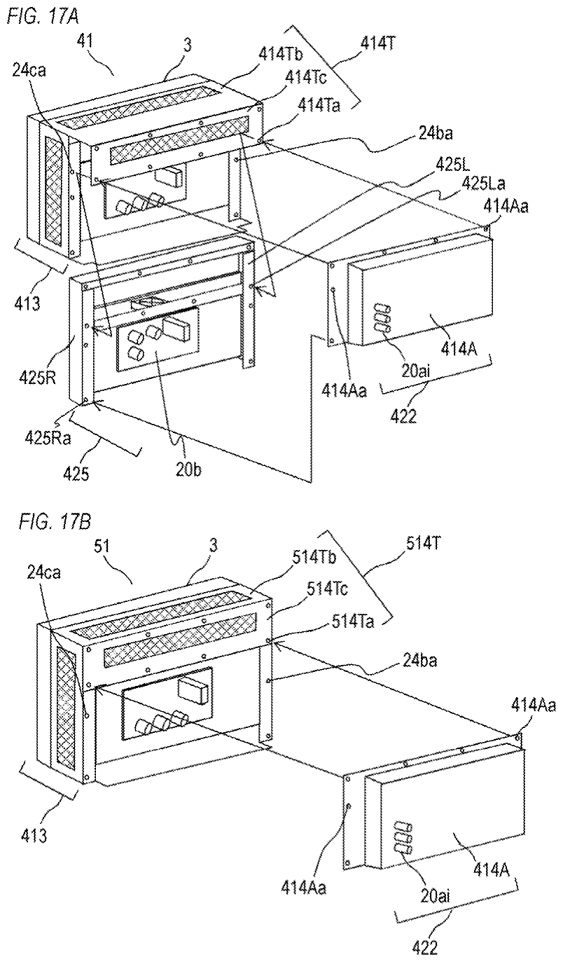

FIGS. 17A and 17B are assembly diagrams of the display apparatus according to the fourth embodiment. FIG. 17A is the assembly diagram of the display apparatus 41 when the brightness is to be further increased, while FIG. 17B is the assembly diagram of a display apparatus 51 when the brightness is not to be further increased.

The upper-surface case 414T includes an upper-surface portion 414Tb extended on the rear-surface side and a rear-surface portion 414Tc curved from a rear-surface-side end of the upper-surface portion 414Tb toward the case 414A. In the rear-surface portion 414Tc, engagement holes (engagement portions) 414Ta thorough which screws or the like are to extend are opened. When a higher brightness is to be achieved in the same manner as in the third embodiment, the intermediate extending unit 425 is mounted between a display module 413 and a main body unit 422. In a right-surface case 425R of the intermediate extending unit 425, engagement portions 425Ra to which screws or the like are to be fastened are provided. In a left-surface case 425L of the intermediate extending unit 425, engagement portions 425La are provided. Each of the engagement portions 425Ra and 425La is disposed on a main body unit side.

When a higher brightness is to be achieved, screws or the like are inserted through engagement holes 414Aa of the case 414A and through the engagement holes 414Ta (portions of the exterior of the display module 413) of the case 414T to be fastened to the engagement portions 425Ra (or the engagement portions 425La) of the intermediate extending unit 425. Thus, the engagement holes 414Aa, the engagement holes 414Ta, and the engagement portions 425Ra (or the engagement portions 425La) are connected to each other to be able to connect the main body unit 422, the intermediate extending unit 425, and the display module 413 to each other.

When a higher brightness is not to be achieved, respective dimensions of the case 414T and the case 14R in the depth direction are not equal to each other. Accordingly, as illustrated in FIG. 17B, a case 514T is attached instead of the case 414T. The case 414T is an exterior which is used when the brightness is to be further increased. When there is no need to further increase the brightness, the case 514T having a width in the depth direction smaller than that of the case 414 is used to configure the display apparatus 51. Similarly to the case 414T, the case 514T has an upper-surface portion 514Tb, a rear-surface portion 514Tc, and engagement holes 514Ta. Screws or the like are inserted through the engagement holes 414Aa of the case 414A and through the engagement holes 514Ta of the case 514T to be fastened to the engagement portions 24ca (or the engagement portions 24ba). As a result, the engagement holes 414Aa, the engagement holes 514Ta, and the engagement portions 24ca (or the engagement portions 24ba) are connected to each other to allow the main body unit 422 to be connected to the display module 413.

As described above, at least positions of some of the engagement portions of the intermediate extending unit coincide with positions of the engagement portions of the display module, and either the engagement portions of the intermediate extending unit or the engagement portions of the display module are connected (fastened) to the engagement holes of the main body unit to be able to configure the display apparatus.

In the fourth embodiment, the description has been given of the example in which the upper-surface case of the display module is extended. However, the case to be extended is not limited to the upper-surface case, and another surface may also be extended.

### Fifth Embodiment

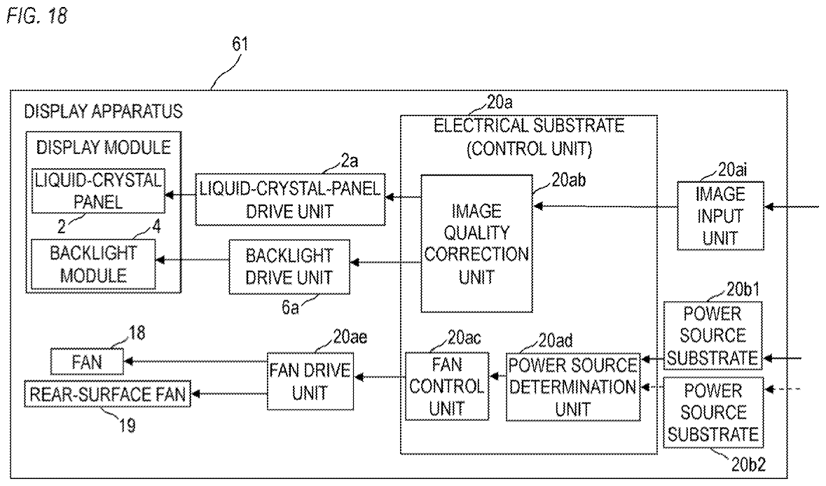

In a fifth embodiment, a description will be given of a control method when a higher brightness is to be achieved in each of the display apparatuses described in the third and fourth embodiments. FIG. 18 is a block diagram of a display apparatus 61 according to the fifth embodiment. The display apparatus 61 has the same configuration as that or the display apparatus 31 according to the third embodiment or that of the display apparatus 41 according to the fourth embodiment.

The display apparatus 61 includes the liquid-crystal panel 2, the backlight module 4, a fan 18 corresponding to the fans 18a to 18f described above, the rear-surface fan 19, and the electrical substrate 20a. A control unit provided on the electrical substrate 20a is hereinafter referred to as a “control unit 20a”. The display apparatus 61 also includes the image input unit 20ai, a power source substrate 20b1, a power source substrate 20b2, a liquid-crystal-panel drive unit 2a, a backlight drive unit 6a, and a fan drive unit 20ae. The power source substrate 20b1 is the power source substrate 20b provided in the main body unit, while the power source substrate 20b2 is the power source substrate 20b provided in the intermediate extending unit. Accordingly, when a higher brightness is not to be achieved, the intermediate extending unit is not attached to the display apparatus 61, and the display apparatus 61 may not include the power source substrate 20b2. When a higher brightness is to be achieved, the intermediate extending unit is attached to the display apparatus 61, and the power source substrate 20b2 is added to the display apparatus 61.

The control unit 20a includes an image quality correction unit 20ab, a fan control unit 20ac, and a power source determination unit 20ad. For example, the control unit 20a is a central processing unit (CPU) and controls an operation of each of the units of the display apparatus 61.

The image quality correction unit 20ab turns ON the backlight module 4 and performs image processing for obtaining the image signal to be displayed on the liquid-crystal panel 2. The image signal obtained by the image correction unit 20ab controls the liquid-crystal panel 2 and the backlight module 4 via the liquid-crystal-panel drive unit 2a that drives the liquid-crystal panel 2 and the backlight drive unit 6a that drives the backlight module 4.

The electrical power (electrical energy) from the outside is input to the power source substrate 20b1 to be used to operate each of the units of the display apparatus 61. For example, the input electrical power drives the fan 18 and the rear-surface fan 19 via the power source determination unit 20ad, the fan control unit 20ac, and the fan drive unit 20ae. When a higher brightness is to be achieved, the electrical power (electrical energy) from the outside is input also to the added power source substrate 20b2. Since the electrical power is input to both of the power source substrate 20b1 and the power source substrate 20b2, the electrical power (electrical energy) that can be used in the display apparatus 61 is higher than that when electrical power is input only to the power source substrate 20b1.

The power source determination unit 20ad determines whether or not the power source substrate 20b2 is added, i.e., whether or not the intermediate extending unit is attached to the display apparatus 61. Based on a result of the determination by the power source determination unit 20ad, the fan control unit 20ac determines conditions for driving the fan 18 and the rear-surface fan 19. Specifically, when it is not required to achieve a higher brightness such as when the power source substrate 20b2 is not added (when the intermediate extending unit is not attached), the fan control unit 20ac determines the conditions so as to reduce speeds of rotations of the fan 18 and the rear-surface fan 19. When the brightness is to be further increased such as when the power source substrate 20b2 is added (when the intermediate extending unit is attached), the fan control unit 20ac determines the conditions so as to increase the speeds of the rotations of the fan 18 and the rear-surface fan 19. The fan drive unit 20ae drives the fan 18 and the rear-surface fan 19 based on the conditions determined by the fan control unit 20ac.

By thus controlling the fans (air blowing member) for flowing the air inside the display apparatus based on whether or not the intermediate extending unit is attached to the display apparatus (based on the required brightness), it is possible to simultaneously inhibit noise and effect heat dissipation from the display apparatus.

Note that each of the third, fourth, and fifth embodiments is only exemplary. A configuration obtained by appropriately modifying or changing a configuration in each of the third, fourth, and fifth embodiments within a scope not departing from the gist of the present invention is also included in the present invention. A configuration obtained by appropriately combining the configurations in the third, fourth, and fifth embodiments is also included in the present invention.

According to the present disclosure, it is possible to reduce, using a simple configuration, noise due to an air blowing member for cooling a display module.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2019-139047, filed on Jul. 29, 2019, and Japanese Patent Application No. 2019-230311, filed on Dec. 20, 2019, which are hereby incorporated by reference herein in their entirety.

What is claimed is:

1. A display apparatus comprising:
a display module configured to display an image; and
an air blowing member provided on a rear-surface side of the display module to blow air toward a rear surface of the display module, wherein
a first exhaust port for exhausting the air blown from the air blowing member to an outside is formed in a side surface of the display apparatus, the first exhaust port being larger in size than a region obtained by projecting, on the side surface, a space formed between the display module and the air blowing member.

2. The display apparatus according to claim 1, wherein
the display module includes a light-emitting module configured to emit light to irradiate a rear surface of a display panel and the display panel configured to transmit the light emitted from the light emitting module to display the image,
the air blowing member blows the air toward a rear surface of the light-emitting module, and
the space is a space formed between the light-emitting module and the air blowing member.

3. The display apparatus according to claim 1, wherein,
in an inner portion of the display apparatus in which the first exhaust port is formed, a space having a width in a front-rear direction of the display apparatus larger than a width between the display module and the air blowing member is formed.

4. The display apparatus according to claim 1, wherein
the first exhaust port is formed so as to include the region obtained through the projection.

5. The display apparatus according to claim 1, wherein
the first exhaust port is formed in at least one of a left surface, a right surface, and an upper surface of the display apparatus.

6. The display apparatus according to claim 1, wherein
the first exhaust port is formed in a surface of the display apparatus different from an upper surface of the display apparatus, and,
in the upper surface of the display apparatus, a second exhaust port for exhausting the air blown from the air blowing member to the outside is formed so as not to include a region obtained by projecting, on the upper surface, the space formed between the display module and the air blowing member.

7. The display apparatus according to claim 1, wherein,
in a lower surface of the display apparatus, an exhaust port for exhausting the air blown from the air blowing member to the outside is not formed.

8. The display apparatus according to claim 1, further comprising:
a columnar member provided on the rear surface of the display module so as to fix the air blowing member to the display module.

9. The display apparatus according to claim 1, wherein
the air blowing member is a fan.

10. The display apparatus according to claim 1, further comprising:
a heat dissipation member provided on the rear surface of the display module.

11. The display apparatus according to claim 10, wherein
the heat dissipation member is a heat sink including a fin.

12. The display apparatus according to claim 11, wherein
the fin is oriented so as to extend along a direction in which the air from the air blowing member flows.

13. A display apparatus comprising:
a display module configured to display an image; and
a main body unit provided on a rear-surface side of the display module, wherein
an intermediate extending unit to be disposed between the display module and the main body unit is attachable to the display apparatus;
when the intermediate extending unit is not attached to the display apparatus, an engagement portion to be located on the rear-surface side of the display module and an engagement portion to be located in the main body unit are disposed so as to be connected to each other; and,
when the intermediate extending unit is attached to the display apparatus, an engagement portion to be located on a main-body-unit side of the intermediate extending unit and the engagement portion located in the main body unit are disposed so as to be connected to each other.

14. The display apparatus according to claim 13, wherein
the intermediate extending unit includes an electrical board.

15. The display apparatus according to claim 14, wherein
the electrical board is an electrical board configured to supply electrical power to the display module.

16. The display apparatus according to claim 14, wherein
the electrical board is an electrical board configured to control the display module.

17. The display apparatus according to claim 13, wherein the display module, the main body unit, and the intermediate extending unit form a first communicating portion connecting a space within the intermediate extending unit to a space within the display module and a second communicating portion connecting the space within the intermediate extending unit to a space within the main body unit.

18. The display apparatus according to claim 13, wherein
the intermediate extending unit includes an electrical board configured to supply electrical power to the display module,
the display apparatus further comprising:
an air blowing member for flowing air inside the display apparatus; and
a control unit that controls the air blowing member based on whether or not the intermediate extending unit is attached to the display apparatus.

19. The display apparatus according to claim 13, wherein,
in the main body unit, an image input unit to which an image signal is to be input is disposed.

20. A display apparatus comprising:
a display module configured to display an image; and
a main body unit provided on a rear-surface side of the display module, wherein
an intermediate extending unit to be disposed between the display module and the main body unit is attachable to the display apparatus;
when the intermediate extending unit is not attached to the display apparatus, an engagement portion to be located on the rear-surface side of the display module and an engagement portion to be located in the main body unit are disposed so as to be connected to each other; and,
when the intermediate extending unit is attached to the display apparatus, an engagement portion to be located on a main-body-unit side of the intermediate extending unit, the engagement portion to be located in the main body unit, and a portion of an exterior of the display module are disposed so as to be connected to each other.
